(19) United States
(12) Patent Application Publication
(10) Pub. No.: US 2017/0288073 A1
(43) Pub. Date: Oct. 5, 2017

(54) PHOTOVOLTAIC DEVICE AND METHODS OF FORMING THE SAME

(71) Applicant: First Solar, Inc., Perrysburg, OH (US)

(72) Inventors: Benyamin Buller, Perrysburg, OH (US); Markus Gloeckler, Perrysburg, OH (US); Akhlesh Gupta, Perrysburg, OH (US); Rick Powell, Perrysburg, OH (US); Rui Shao, Perrysburg, OH (US); Gang Xiong, Perrysburg, OH (US); Ming Lun Yu, Perrysburg, OH (US); Zhibo Zhao, Perrysburg, OH (US)

(73) Assignee: First Solar, Inc., Perrysburg, OH (US)

(21) Appl. No.: 15/619,674

(22) Filed: Jun. 12, 2017

Related U.S. Application Data
(62) Division of application No. 14/317,433, filed on Jun. 27, 2014.
(60) Provisional application No. 61/839,930, filed on Jun. 27, 2013.

(51) Int. Cl. H01L 31/0224; H01L 31/073; H01L 31/0749

(52) U.S. Cl. CPC H01L 31/022425; H01L 31/0749; Y02E 10/543; Y02E 10/541; H01L 31/073; Y02P 70/521

(57) ABSTRACT

Methods and devices are described for a photovoltaic device. The photovoltaic device includes a glass substrate, a semiconductor absorber layer formed over the glass substrate, a metal back contact layer formed over the semiconductor absorber layer, and a p-type back contact buffer layer formed from one of MnTe, Cd₁₋ₓMnₓTe, and SnTe, the buffer layer disposed between the semiconductor absorber layer and the metal back contact layer.

### CROSS-REFERENCE TO RELATED APPLICATION

This is a divisional application of U.S. patent application Ser. No. 14/317,433, filed on Jun. 27, 2014; which claims the benefit of priority of U.S. Provisional Patent Application No. 61/839,930, filed on Jun. 27, 2013. The entire disclosures of all the aforementioned applications are hereby incorporated herein by reference for all purposes.

### FIELD OF THE INVENTION

The present disclosure relates generally to the field of photovoltaic devices, and more particularly to the structure and methods of producing photovoltaic devices.

### BACKGROUND OF THE INVENTION

During the fabrication of photovoltaic devices, layers of semiconductor material can be applied to a substrate with one layer serving as a window layer and a second layer serving as an absorber layer. In addition to the semiconductor layer (the window and absorber layers), photovoltaic modules, devices, or cells, can include multiple layers (or coatings) created on a substrate (or superstrate). For example, a photovoltaic device can include a barrier layer, a transparent conductive oxide layer, a buffer layer, and a semiconductor layer formed in a stack on a substrate. Each layer may in turn include more than one layer or film. For example, a semiconductor window layer and a semiconductor absorber layer together can be considered a semiconductor layer. Additionally, each layer can cover all or a portion of the device and/or all or a portion of a layer or a substrate underlying the layer. For example, a “layer” can include any amount of any material that contacts all or a portion of a surface. Cadmium telluride has been used for the semiconductor layer because of its optimal band structure and a low cost of manufacturing.

Maximizing the efficiency of photovoltaic devices remains a long-standing goal of photovoltaic device manufacturers and users. It is often desirable to minimize a thickness of the layers of a photovoltaic device. As the thickness of the layers decreases, any defect within one of the layers and at the junction of adjacent layers becomes more pronounced. One such defect may be current-shunting, short circuit defects. These process-related defects are thought to either be present in the morphology of the substrate electrode, or develop during the deposition or subsequent processing of semiconductor absorber layers. Shunt defects may be present in photovoltaic devices when one or more low resistance current paths develop through the semiconductor absorber layer, allowing current to pass unimpeded between electrodes of the photovoltaic device.

An outstanding concern in achieving high-efficiency photovoltaic devices formed from a CdS/CdTe semiconductor absorber layer is the formation of a low-resistance contact to the CdTe layer. According to traditional theory of ohmic contact formation, a metal forming an ohmic contact to the CdTe should have a Fermi level aligned with a top of the valence band of the CdTe. However, due to a high end for a work function of CdTe, most metals are incapable of matching the work function and thus are not as efficient for making ohmic contact to CdTe.

It would be desirable to develop a photovoltaic device having a back contact buffer layer that provides a low-resistance contact between a semiconductor absorber layer and the back contact layer to increase an efficiency of the device.

### SUMMARY OF THE INVENTION

Concordant and congruous with the instant disclosure, a photovoltaic device having a back contact buffer layer that provides a low-resistance contact between a semiconductor absorber layer and the back contact layer to increase an efficiency of the device has surprisingly been discovered.

In an embodiment of the invention, a photovoltaic device comprises a glass substrate; a semiconductor absorber layer formed over the glass substrate; a metal back contact layer formed over the semiconductor absorber layer; and a p-type back contact buffer layer disposed between the semiconductor absorber layer and the metal back contact layer.

In another embodiment, a method of manufacturing a photovoltaic device comprises the steps of depositing a semiconductor absorber layer adjacent to a substrate; depositing a p-type back contact buffer layer adjacent to the semiconductor absorber layer; and depositing a back contact layer adjacent to the p-type back contact buffer layer.

In another embodiment, a method of manufacturing a photovoltaic device comprises the steps of depositing a CdS window layer adjacent to a substrate; depositing a CdTe semiconductor absorber layer adjacent to the CdS window layer; depositing a p-type back contact buffer layer consisting of either MnTe or SnTe adjacent to the CdTe semiconductor absorber layer; and depositing a back contact layer adjacent to the p-type back contact buffer layer.

### DRAWINGS

The above, as well as other advantages of the present disclosure, will become readily apparent to those skilled in the art from the following detailed description, particularly when considered in the light of the drawings described hereafter.

FIG. 1 is a schematic of a photovoltaic device as known in the art;

FIG. 2 is an energy band diagram of the photovoltaic device of FIG. 1;

FIG. 3 is a schematic of a photovoltaic device according to the invention;

FIG. 4 is an energy band diagram of one embodiment of the photovoltaic device of FIG. 3 and

FIG. 5 is an energy band diagram of another embodiment of the photovoltaic device of FIG. 3.

### DETAILED DESCRIPTION OF THE INVENTION

The following description is merely exemplary in nature and is not intended to limit the present disclosure, application, or uses. It should also be understood that throughout the drawings, corresponding reference numerals indicate like or corresponding parts and features. In respect of the methods disclosed, the order of the steps presented is exemplary in nature, and thus, is not necessary or critical unless recited otherwise.

FIG. 1 is a schematic representation of a photovoltaic device 10 as known in the art. The photovoltaic device 10 includes a glass substrate 12 on which a thin conductive oxide (TCO) layer 14, formed from a F-doped SnO₂, for example, is deposited. A buffer layer 16, formed from SnO₂, for example, is deposited on the TCO layer 14. The buffer layer 16 may also be formed from a zinc tin oxide, cadmium tin oxide, or other transparent semiconducting oxide or a combination thereof, as desired. The CdS buffer layer is option, and if the layer is present it may be continuous or non-continuous and the layer may cover all or a portion of the device and/or all or a portion of a layer or a substrate underlying the buffer layer. An n-type window layer 18, formed from CdS, for example, is deposited on the buffer layer 16, followed by a p-type semiconductor absorber layer 20, formed from CdTe, for example. The absorber layer 20 may also be formed from CdZnTe, CdSTe, CIGS, amorphous silicon, crystalline silicon, or GaAs, for example, as desired. A metal back contact 22 is deposited or formed on the absorber layer 20. The back contact may be formed from MoNₓ/Al, ZnTe:Cu, CdSe, MgTe, HgTe, or ZnTe/Al bilayer other suitable semiconductor/metal multilayers, and the like, for example.

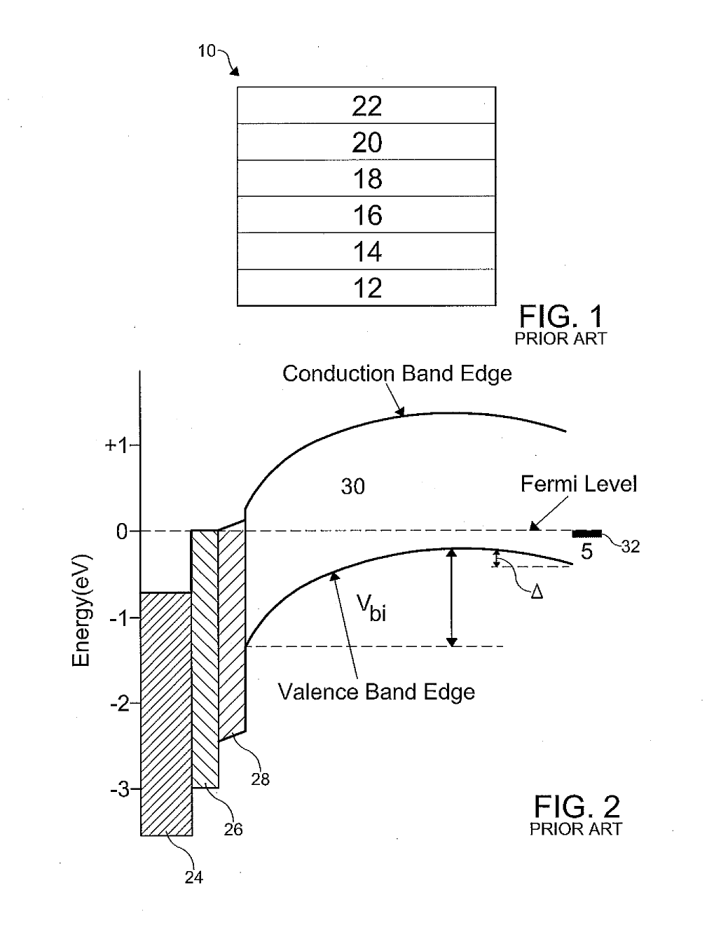

An exemplary energy band diagram of the photovoltaic device of FIG. 1 is shown in FIG. 2. Band gap energy for the TCO layer 14 is depicted as 24, band gap energy of the buffer layer 16 is depicted as 26, band gap energy of the window layer 18 is depicted as 28, band gap energy of the absorber layer 20 is depicted as 30, and the band gap energy of the back contact layer 22 is depicted as 32. As shown in FIG. 2, the conduction band edge and the valence band edge bend downward by A near the junction of the absorber layer 20 and the back contact layer 22. This is due to the back contact layer 22 having a lower work function than that of the absorber layer 20. The downward bending of the band edges increases an electron diffusion current into the back contact layer 22 and limits a maximum achievable open-circuit voltage V_{oc} to V_{bi}−Δ. V_{bi} (built-in potential) is described as an upper limit to the open-circuit voltage (V_{oc}) of a photovoltaic device under illumination. Therefore, a decrease in V_{bi} by an amount, Δ, is a decrease in the upper limit to the maximum achievable V_{oc}.

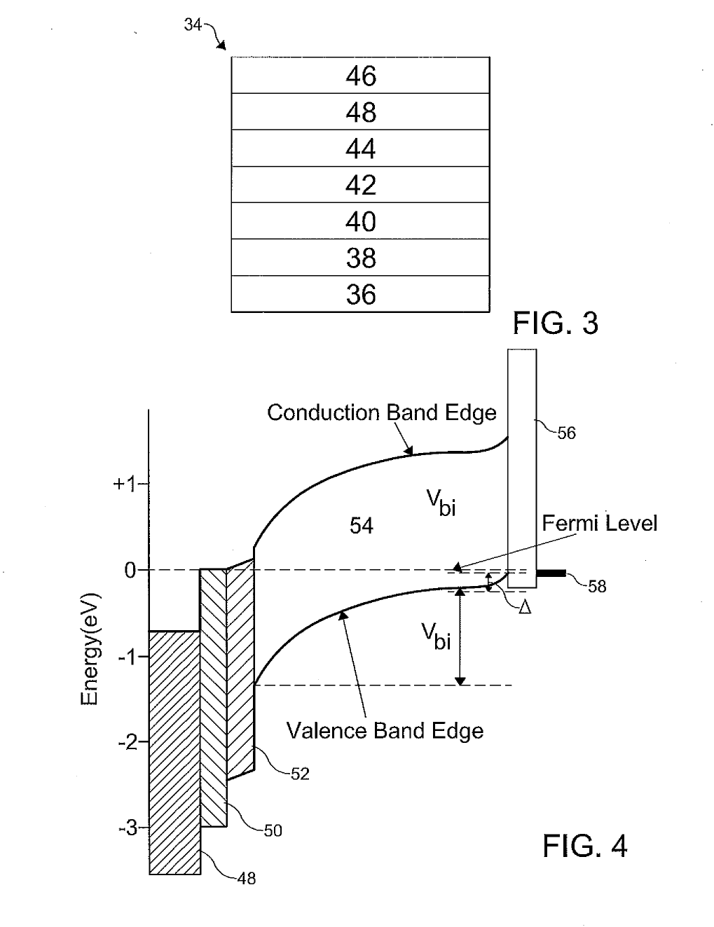

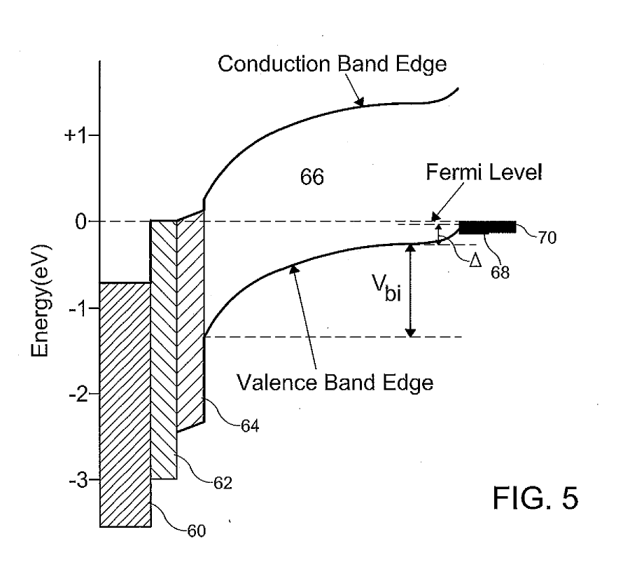

FIG. 3 is a schematic representation of a photovoltaic device 34 according to an embodiment of the invention. The photovoltaic device 34 includes a substrate layer 36, a TCO layer 38, a buffer layer 40, a window layer 42, a semiconductor absorber layer 44, and a back contact layer 46 similar to those described with respect to the layers of the photovoltaic device 10. However, the photovoltaic device 34 includes a back contact buffer layer 48 disposed between the back contact layer 46 and the absorber layer 44. The back contact buffer layer 48 is formed from a p-type material, such as SnTe, MnTe, or Cd₁₋ₓMnₓTe. MnTe and SnTe are particularly suitable as materials for forming the back contact buffer layer 48 due to good lattice structure matches with the CdTe semiconductor absorber layer 44. MnTe and SnTe are also particularly suitable due to having a higher hole concentrations than CdTe to induce an upward band bending in CdTe to reduce electron diffusion into the back contact layer 46, as illustrated in FIGS. 4 and 5 and discussed further herein below. The back contact buffer layer 48 improves band alignment between the back contact layer 46 and the absorber layer 44 which leads to an optimized performance of the photovoltaic device 34.

Similarly, Cd₁₋ₓMnₓ Te is a suitable back contact buffer layer 48 because the presence of

Mn with CdTe increases a room temperature band gap thereof linearly with a Mn faction x at the rate of about 13 mV/% Mn up to x=about 0.5. That is, a maximum band gap increase is obtainable for Cd_{0.5}Mn_{0.5}Te, though x may be between 0 and about 1, as desired. Furthermore, Cd₁₋ₓMnₓTe has a very small mismatch, about 1%, with CdTe. Therefore, an amount of interface states at a junction between CdTe and Cd₁₋ₓMnₓTe is minimized, thereby optimizing performance of the photovoltaic device. A Cd₁₋ₓMnₓTe back contact buffer layer may be prepared using techniques such as metalorganic chemical vapor deposition (MOCVD), sputtering, and molecular beam epitaxy (MBE), for example.

Favorable results have been obtained using the back contact buffer layer 48 formed from MnTe for at least the following reasons: MnTe has low vapor pressure suitable for vapor transport deposition (VTD) processes; about 100% solubility in CdTe; a band gap of about 3.2 eV; and due to Mn vacancies, the MnTe may be doped up to about 10¹⁹ cm⁻³. The MnTe back contact buffer layer 48 may be deposited on the absorber layer 44 using known deposition processes, but positive results have been obtained using a high temperature evaporation process, a sputtering processing

For example, to form the device 34 having the MnTe back contact buffer layer 48 using high temperature evaporation or sputtering processes, the window layer 42 and absorber layer 44 are deposited using VTD processes on a TEC10 glass substrate 36. The window layer 42 and the absorber layer 44 are then treated with CdCl₂, as known in the art. The surface of the CdCl₂-treated absorber layer 44 is then cleaned with a dilute HCl solution. When using an evaporation process, a MnTe source is then heated to evaporate the MnTe. The evaporated MnTe is then impinged upon the absorber layer 44 to deposit the MnTe back contact buffer layer 48 thereon. Alternatively when using a sputtering process, MnTe may be sputtered onto the absorber layer 44 with a MnTe target with a temperature of the substrate layer 36 from about room temperature to about 300° C. The target thickness of the back contact buffer layer 48 is from about 10 nm to about 500 nm. Once the MnTe back contact buffer layer 48 is deposited, processing of the device 34 continues through to packaging.

FIG. 4 shows a band energy band diagram of the photovoltaic device 34 of FIG. 3 where the back contact buffer layer 48 is formed from MnTe. Band gap energy for the TCO layer 38 is depicted as 48, band gap energy of the buffer layer 40 is depicted as 50, band gap energy of the window layer 42 is depicted as 52, band gap energy of the absorber layer 44 is depicted as 54, the band gap energy of the MnTe back contact buffer layer 48 is depicted 56, and the band gap energy of the back contact layer 46 is depicted as 58. As shown in FIG. 4, the higher work function of the MnTe back contact buffer layer 48 causes an upward CdTe band bending A when the MnTe back contact buffer layer 48 is deposited on the CdTe absorber layer 44. Because MnTe has a higher conduction band edge than CdTe, i.e. a conduction band offset of about 1.7 eV, the MnTe back contact buffer layer 48 performs as an electron reflector, thereby substantially minimizing, if not eliminating, diffusion of electrons into the back contact layer 46. Due to the upward band bending A, a higher limit on achievable V_{oc} is increased to V_{bi+Δ}, thereby improving the performance of the photovoltaic device 34.

Using the back contact buffer layer 48 formed from SnTe may have favorable results for the following reasons: SnTe has a vapor pressure of about 0.03 atm at 1000° C., only slightly higher than that of CdS; a work function of about 5.1 eV; a band gap of from about 0.2 eV to about 0.3 eV; a melting point at about 795° C.; and due to Sn vacancies, the SnTe may be intrinsically doped up to about 1.5×10²¹ cm⁻³ at room temperature. The SnTe may be deposited on the absorber layer 44 using known deposition processes, but favorable results may be obtained using a VTD process and a sputtering process.

To form the device 34 having the SnTe back contact buffer layer using the VTD process, the window layer 42 and absorber layer 44 are deposited using VTD processes on the TEC10 glass substrate 36. The SnTe is deposited on the absorber layer 44 using a VTD process with the same or similar conditions as the VTD process to deposit the CdS since SnTe has a similar vapor pressure thereto. The target thickness of the SnTe back contact buffer layer 48 is from about 10 nm to about 500 nm. Prior to deposition of the SnTe back contact buffer layer 48, the window layer 42 and the absorber layer 44 are then treated with CdCl₂, and the surface of the CdCl₂-treated absorber layer may then be cleaned with a dilute HCl solution.

To form the device 34 having the SnTe back contact buffer layer 48 using the sputtering process, the window layer 42 and absorber layer 44 are deposited using VTD processes on the TEC10 glass substrate 36. The window layer 42 and the absorber layer 44 are then treated with CdCl₂. The surface of the CdCl₂-treated absorber layer is then cleaned with a dilute HCl solution. SnTe is sputtered onto the absorber layer 44 with a SnTe target at a temperature of from about room temperature to about 300° C. The target thickness of the back contact buffer layer 48 is from about 10 nm to about 500 nm. Once the SnTe back contact buffer layer 48 is deposited, processing of the device 34 continues through to packaging.

FIG. 5 shows an energy band diagram of the photovoltaic device 34 of FIG. 3 where the back contact buffer layer 48 is formed from SnTe. Band gap energy for the TCO layer 38 is depicted as 60, band gap energy of the buffer layer 40 is depicted as 62, band gap energy of the window layer 42 is depicted as 64, band gap energy of the absorber layer 44 is depicted as 66, the band gap energy of the MnTe back contact buffer layer 48 is depicted 68, and the band gap energy of the back contact layer 46 is depicted as 70. As shown in FIG. 4, the higher work function of the SnTe back contact buffer layer 48 causes an upward CdTe band bending A when the SnTe back contact buffer layer 48 is deposited on the CdTe absorber layer 44. Due to the upward band bending A, a higher limit on achievable V_{oc} is increased to V_{bi}+Δ. Furthermore, the SnTe back contact buffer layer 48 performs as an electron reflector, thereby substantially minimizing, if not eliminating, diffusion of electrons into the back contact layer 46.

While certain representative embodiments and details have been shown for purposes of illustrating the invention, it will be apparent to those skilled in the art that various changes may be made without departing from the scope of the disclosure, which is further described in the following appended claims.

What is claimed is:

1. A method of manufacturing a photovoltaic device comprising the steps of:
depositing a semiconductor absorber layer on a substrate, wherein the semiconductor absorber layer is formed from CdTe;
depositing a p-type back contact buffer layer on the semiconductor absorber layer, wherein the p-type back contact buffer layer is formed from MnTe, and wherein the depositing a p-type back contact buffer layer step is an evaporation step whereby the MnTe back contact buffer layer is deposited on the semiconductor absorber layer by impinging evaporated MnTe onto the semiconductor absorber layer, the evaporated MnTe generated by heating a source of MnTe; and
depositing a back contact layer on the p-type back contact buffer layer.

2. The method of claim 1, wherein the evaporation step is performed at a temperature of up to about 1200° C.

3. The method of claim 1, wherein the MnTe is doped up to about 10¹⁹ cm⁻³.

4. A method of manufacturing a photovoltaic device comprising the steps of:
depositing a semiconductor absorber layer on a substrate, wherein the semiconductor absorber layer is formed from CdTe;
depositing a p-type back contact buffer layer on the semiconductor absorber layer, wherein the depositing a p-type back contact buffer layer step is a sputtering step whereby the MnTe back contact buffer layer is deposited on the semiconductor absorber layer by sputtering MnTe with a MnTe target onto the semiconductor absorber layer; and
depositing a back contact layer on the p-type back contact buffer layer.

5. The method of claim 4, wherein the sputtering step is performed at a temperature of up to about 300° C.

6. The method of claim 4, wherein the MnTe is doped up to about 10¹⁹ cm⁻³.

7. A method of manufacturing a photovoltaic device comprising the steps of:
depositing a semiconductor absorber layer on a substrate, wherein the semiconductor absorber layer is formed from CdTe;
depositing a p-type back contact buffer layer on the semiconductor absorber layer, wherein the depositing a p-type back contact buffer layer step is a chemical reaction step involving:
a. depositing MnI₂ solution onto the semiconductor absorber layer by one of application of liquid MnI₂ thereon and evaporating MnI₂ onto thereon; and
b. annealing the MnI₂-coated semiconductor absorber layer to form the p-type back contact; and
depositing a back contact layer on the p-type back contact buffer layer.

8. The method of claim 7, wherein the annealing step is conducted at a temperature of from about 400° C. to about 650° C. in an oxygen-deficient environment.

9. The method of claim 7, wherein the annealing step is conducted in the presence of a flow of an inert gas to remove annealing byproduct gases.

10. The method of claim 7, wherein the p-type back contact buffer layer is formed from SnTe.

11. The method of claim 10, wherein the depositing a p-type back contact buffer layer step is a sputtering step whereby the SnTe back contact buffer layer is deposited on the semiconductor absorber layer by sputtering SnTe with a SnTe target onto the semiconductor absorber layer.

12. The method of claim 10, wherein the depositing a p-type back contact buffer layer step is a vapor transport deposition step whereby SnTe is deposited on the semiconductor absorber layer.

13. The method of claim 10, wherein the SnTe back contact buffer layer has a thickness from about 10 nm to about 500 nm.

14. The method of claim 7, wherein the p-type back contact buffer layer is formed from Cd₁₋ₓMnₓTe.

15. The method of claim 14, wherein the Cd₁₋ₓMnₓTe comprises Cd_{0.5}Mn_{0.5}Te.
